(19) United States
(12) Patent Application Publication
(10) Pub. No.: US 2026/0311624 A1
(43) Pub. Date: Oct. 8, 2026

(54) SHIFT REGISTER, DISPLAY SUBSTRATE, AND DISPLAY DEVICE

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Yao HUANG, Beijing (CN); Rong WANG, Beijing (CN); Xiangdan DONG, Beijing (CN); Haijun QIU, Beijing (CN); Ming HU, Beijing (CN); Yongliang ZHAO, Beijing (CN)

(21) Appl. No.: 19/483,154

(22) PCT Filed: May 14, 2024
(86) PCT No.: PCT/CN2024/093140

§ 371 Date: Nov. 10, 2025

(30) Foreign Application Priority Data
Jun. 21, 2023 (CN) 202310745094.4

(51) Int. Cl. G09G 3/20; G11C 19/28

(52) U.S. Cl. CPC G09G 3/2092; G11C 19/28; G09G 2300/0408; G09G 2300/0426; G09G 2300/0852; G09G 2310/0267; G09G 2310/0286

(57) ABSTRACT

A shift register includes: a first input subcircuit configured to transmit a first level signal to a first node in response to a first clock signal; a second input subcircuit configured to transmit an input signal to a second node in response to the first clock signal; a control subcircuit configured to input a second level signal to the first node in response to a second clock signal; a protection subcircuit configured to, when the second input subcircuit is not working, input a voltage of a third node to the second node, and enable a voltage of the second node to be lower than the third node; a first output subcircuit configured to output the second level signal in response to a voltage of the first node; and a second output subcircuit configured to output the second clock signal in response to the voltage of the third node.

### CROSS-REFERENCE TO RELATED APPLICATION

This is a National Phase Application filed under 35 U.S.C. 371 as a national stage of PCT/CN2024/093140, filed on May 14, 2024, an application claiming the benefit of Chinese Application No. 202310745094.4 filed on Jun. 21, 2023, the content of each of which is hereby incorporated by reference in its entirety.

### TECHNICAL FIELD

The present disclosure relates to the field of display technology, and specifically relates to a shift register, a display substrate, and a display device.

### BACKGROUND

With the continuous development of the display technology, the development of displays in recent years gradually shows the trend of high integration and low cost. One of the most important technologies is the mass production implemented by Gate Driver on Array (GOA).

A shift register circuit composed of thin film transistors (TFTs) is integrated on an array substrate of a display substrate by the GOA technology to form scan driving on the display substrate, so that a gate driver integrated circuit part can be omitted, which can not only reduce the product cost in terms of the material cost and the manufacturing process, but also enable an aesthetic design of the display substrate with symmetrical sides and a narrow bezel.

### SUMMARY

To solve at least one of the technical problems in the existing art, the present disclosure provides a shift register, a display substrate, and a display device.

In a first aspect, an embodiment of the present disclosure provides a shift register, wherein the shift register includes: a first input subcircuit, a second input subcircuit, a control subcircuit, a protection subcircuit, a first output subcircuit, and a second output subcircuit;
the first input subcircuit is configured to transmit a first level signal to a first node in response to a first clock signal; and the first node is a connection point between the first input subcircuit, the first output subcircuit, and the control subcircuit;
the second input subcircuit is configured to transmit an input signal to a second node in response to the first clock signal; and the second node is a connection point between the second input subcircuit and the protection subcircuit;
the control subcircuit is configured to input a second level signal to the first node in response to a second clock signal;
the protection subcircuit is configured to, when the second input subcircuit is working, transmit a voltage of the second node to a third node; and when the second input subcircuit is not working, input a voltage of the third node to the second node, and enable the voltage of the second node to be lower than the voltage of the third node; and the third node is a connection point between the protection subcircuit and the second output subcircuit;
the first output subcircuit is configured to output the second level signal in response to a voltage of the first node; and
the second output subcircuit is configured to output the second clock signal in response to the voltage of the third node.

Optionally, the first input subcircuit includes: a third transistor; wherein
the third transistor has a control electrode electrically connected to a first clock signal line, a first electrode electrically connected to a first level signal line, and a second electrode electrically connected to the first node.

Optionally, the second input subcircuit includes: a first transistor; wherein
the first transistor has a control electrode electrically connected to the first clock signal line, a first electrode electrically connected to a signal input, and a second electrode electrically connected to the second node.

Optionally, the protection subcircuit includes: a sixth transistor; wherein
the sixth transistor has a control electrode electrically connected to a first level signal line, a first electrode electrically connected to the second node, a second electrode electrically connected to the third node.

Optionally, the control subcircuit includes: a second transistor; wherein
the second transistor has a control electrode electrically connected to a second clock signal line, a first electrode electrically connected to a second level signal line, and a second electrode electrically connected to the first node.

Optionally, the first output subcircuit includes: a fifth transistor and a first storage capacitor;
the fifth transistor has a control electrode electrically connected to the first node, a first electrode electrically connected to the second level signal line, and a second electrode electrically connected to a signal output; and
the first storage capacitor has one end electrically connected to the first node, and the other end electrically connected to the second level signal line.

Optionally, the second output subcircuit includes: a fourth transistor and a second storage capacitor;
the fourth transistor has a control electrode electrically connected to the third node, a first electrode electrically connected to the second clock signal line, and a second electrode electrically connected to the signal output; and
the second storage capacitor has one end electrically connected to the third node, and the other end electrically connected to the signal output.

Optionally, the transistors in the subcircuits are all oxide thin film transistors.

Optionally, a width-to-length ratio of the second transistor is greater than a width-to-length ratio of the third transistor.

In a second aspect, an embodiment of the present disclosure further provides a shift register, wherein the shift register includes: a first transistor, a second transistor, a third transistor, a fourth transistor, a fifth transistor, a sixth transistor, a first storage capacitor, and a second storage capacitor;
the third transistor has a control electrode electrically connected to a first clock signal line, a first electrode electrically connected to a first level signal line, and a second electrode electrically connected to a first node;
the first transistor has a control electrode electrically connected to the first clock signal line, a first electrode electrically connected to a signal input, a second electrode electrically connected to a second node;
the sixth transistor has a control electrode electrically connected to the first level signal line, a first electrode electrically connected to the second node, and a second electrode electrically connected to a third node;
the second transistor has a control electrode electrically connected to a second clock signal line, a first electrode electrically connected to a second level signal line, and a second electrode electrically connected to the first node;
the fifth transistor has a control electrode electrically connected to the first node, a first electrode electrically connected to the second level signal line, and a second electrode electrically connected to a signal output;
the first storage capacitor has one end electrically connected to the first node, and the other end electrically connected to the second level signal line;
the fourth transistor has a control electrode electrically connected to the third node, a first electrode electrically connected to the second clock signal line, and a second electrode electrically connected to the signal output; and
the second storage capacitor has one end electrically connected to the third node, and the other end electrically connected to the signal output.

In a third aspect, an embodiment of the present disclosure provides a display substrate, wherein the display substrate includes: a base substrate, and a plurality of shift registers, each being the shift register as described above, cascaded together on the base substrate.

Optionally, the display substrate further includes: a plurality of clock signal lines and a plurality of power signal lines; the clock signal lines include at least: a first clock signal line and a second clock signal line; and the power signal lines include at least: a first level signal line and a second level signal line;
the plurality of clock signal lines and the plurality of power signal lines extend in a first direction, and are arranged side by side in a second direction, wherein the first direction is intersected with the second direction; and
a width of each clock signal line in the second direction is greater than a width of each power signal line in the second direction.

Optionally, a first transistor, a second transistor, a third transistor, and a sixth transistor in each shift register are in a first transistor group; and
active layers in the first transistor group are arranged in the first direction, and arranged side by side in the first direction.

Optionally, each active layer in the first transistor group is between adjacent power signal lines, and a width of each active layer in the second direction is less than a distance between the adjacent power signal lines.

Optionally, a width of each active layer in the first transistor group in the second direction is less than the width of each clock signal line in the second direction, and greater than or equal to the width of each power signal line in the second direction.

Optionally, a width of the first transistor group in the second direction is less than the width of each clock signal line in the second direction, and greater than or equal to the width of each power signal line in the second direction.

Optionally, a fourth transistor and a fifth transistor in each of the shift registers are in a second transistor group; and
active layers in the second transistor group are arranged in a first direction, and arranged side by side in the second direction.

Optionally, each active layer in the second transistor group is on a side of the power signal lines away from the clock signal lines.

Optionally, a width of each active layer in the second transistor group in the second direction is greater than a width of each clock signal line in the second direction.

Optionally, an orthographic projection of the first storage capacitor on the base substrate is between an orthographic projection of the first level signal line on the base substrate and an orthographic projection of the fourth transistor on the base substrate; and
an orthographic projection of the second storage capacitor on the base substrate is on a side of an orthographic projection of the fifth transistor on the base substrate away from the second level signal line.

Optionally, the orthographic projection of the first storage capacitor on the base substrate is at least partially overlapped with the orthographic projection of the second level signal line on the base substrate.

In a fourth aspect, an embodiment of the present disclosure provides a display device, wherein the display device includes the display substrate as described above.

### BRIEF DESCRIPTION OF FIGURES

FIG. 1 is a schematic circuitry diagram of an exemplary shift register.

FIG. 2 is a schematic plan view of the shift register in FIG. 1.

FIG. 3 is a schematic circuitry diagram of a shift register according to an embodiment of the present disclosure.

FIG. 4 is a schematic plan view of the shift register in FIG. 3.

FIG. 5 is a timing diagram of the shift register in FIG. 3.

FIG. 6 is a schematic circuitry diagram of another shift register according to an embodiment of the present disclosure.

FIG. 7A is a schematic structural diagram of a first gate conductive layer in a display substrate according to an embodiment of the present disclosure.

FIG. 7B is a schematic structural diagram of a second gate conductive layer in a display substrate according to an embodiment of the present disclosure.

FIG. 7C is a schematic structural diagram of a semiconductor layer in a display substrate according to an embodiment of the present disclosure.

FIG. 7D is a schematic structural diagram of a third gate conductive layer in a display substrate according to an embodiment of the present disclosure.

FIG. 7E is a schematic structural diagram of a source/drain conductive layer in a display substrate according to an embodiment of the present disclosure.

FIG. 7F is a laminated structure of the layers in FIGS. 7A to 7E.

### DETAILED DESCRIPTION

To improve understanding of the technical solution of the present disclosure for those skilled in the art, the present disclosure will be described in detail below with reference to accompanying drawings and specific implementations.

Unless otherwise defined, technical or scientific terms used in the present disclosure are intended to have general meanings as understood by those of ordinary skill in the art to which the present disclosure belongs. The words “first”, “second” and similar terms used in the present disclosure do not denote any order, quantity, or importance, but are used merely for distinguishing different components from each other. Likewise, the words “a”, “an”, or “the” and similar referents do not denote a limitation of quantity, but rather denote the presence of at least one. The word “comprise” or “include” or the like means that the element or item preceding the word contains elements or items that appear after the word or equivalents thereof, but does not exclude other elements or items. The terms “connected” or “coupled” and the like are not restricted to physical or mechanical connection, but may include electrical connection, either direct or indirect. The words “upper”, “lower”, “left”, “right”, or the like are merely used to indicate a relative positional relationship, and when an absolute position of the described object is changed, the relative positional relationship may be changed accordingly.

It should be noted here that the transistors used in the embodiments of the present disclosure may be thin film transistors or field effect transistors or any other device with the same characteristics, and since the source and the drain of a transistor are symmetrical, there is no difference between a source and a drain. In the embodiments of the present disclosure, for distinguishing purposes, one of the source or the drain of the transistor is referred to as a first electrode, while the other is referred to as a second electrode, and the gate is referred to as a control electrode. In addition, transistors may be classified into N-type transistors and P-type transistors according to the characteristics of the transistors. The embodiments below are described taking an N type transistor as an example. When an N-type transistor is adopted, the first electrode is a source of the N-type transistor, and the second electrode is a drain of the N-type transistor, and when a high level is input into the gate, the source and the drain are electrically connected. For a P type, the contrary is true. It is contemplated that the implementation with a P-type transistor can be easily conceived by those skilled in the art without any creative effort, and therefore, also falls within the scope of the embodiments of the present disclosure. In addition, depending on the material of an active layer in the transistors, the transistors may be classified into oxide thin film transistors, low temperature polysilicon thin film transistors, and the like. Generally, the oxide thin film transistors are N-type transistors, and the low temperature polysilicon thin film transistors are P-type transistors.

Since the transistors used in the embodiments of the present disclosure are N-type transistors, a working level signal in the embodiments of the present disclosure, i.e., the first level signal, is a high-level signal, and a non-working level signal, i.e., the second level signal, is a low-level signal. Accordingly, the first level signal line is a high-level signal line, and the second level signal line is a low-level signal line.

Generally, a display substrate includes a plurality of gate lines and a plurality of data lines, which are arranged in a crossed manner to define a plurality of pixel regions each provided with pixel units. The structure of the display substrate will be described below by taking an extending direction of each gate line as a row direction and an extending direction of each data line as a column direction as an example. When the display substrate is driven to display, depending on the picture to be displayed, a scanning signal may be written to the gate lines progressively, while a data voltage signal is written to the data lines, so that pixel units in the display substrate are lightened progressively.

The scanning signal is provided by a gate driver circuit, and the data voltage signal is provided by a source driver circuit. In the existing art, the gate driver circuit may be integrated in a gate driver chip, and the source driver circuit may be integrated in a source driver chip. However, to reduce the number of chips and enable narrow-bezel or bezel-less display, a technology for integrating the gate driver circuit on an array substrate (Gate On Array; GOA) has been proposed, in which the gate driver circuit includes a plurality of cascaded shift registers which are integrated on the array substrate and electrically connected to gate lines in one-to-one correspondence to provide a gate scanning signal for the gate lines electrically connected thereto.

To further clarify how the shift register implements the output of the scanning signal, the following description is made in conjunction with a specific example of the shift register.

FIG. 1 is a schematic circuitry diagram of an exemplary shift register. As shown in FIG. 1, the shift register includes: a first transistor T1, a second transistor T2, a third transistor T3, a fourth transistor T4, a fifth transistor T5, a sixth transistor T6, a seventh transistor T7, an eighth transistor T8, a first storage capacitor C1, and a second storage capacitor C2.

The first transistor T1 has a gate electrically connected to a first clock signal line GCK, a source electrically connected to a signal input Input, and a drain electrically connected to a first node N1. The first node N1 is a connection point between the drain of the first transistor T1, a gate of the second transistor T2, a source of the seventh transistor T7, and a source of the eighth transistor T8.

The second transistor T2 has a gate electrically connected to the first node N1, a source electrically connected to the first clock signal line GCK, and a drain electrically connected to a second node N2. The second node N2 is a connection point between the drain of the second transistor T2, a drain of the third transistor T3, a gate of the sixth transistor T6, a gate of the fourth transistor T4, and one end of the first storage capacitor C1.

The third transistor T3 has a gate electrically connected to the first clock signal line GCK, a source electrically connected to a low-level signal line VGL, and a drain electrically connected to the second node N2.

The fourth transistor T4 has a gate electrically connected to the second node N2, a source electrically connected to a high-level signal line VGH and the other end of the first storage capacitor C2, and a drain electrically connected to a signal output.

The fifth transistor T5 has a gate electrically connected to a third node N3, a source electrically connected to a second clock signal line GCB, and a drain electrically connected to the signal output Output and the other end of the second storage capacitor C2. The third node N3 is a connection point between the gate of the fifth transistor T5, a drain of the eighth transistor T8, and one end of the second storage capacitor C2.

The sixth transistor T6 has a gate electrically connected to the second node N2, a source electrically connected to a high-level signal line VGH, and a drain electrically connected to a source of the seventh transistor T7.

The seventh transistor T7 has a gate electrically connected to the second clock signal line GCB, the source electrically connected to the drain of the sixth transistor T6, and a drain electrically connected to the first node N1.

The eighth transistor T8 has a gate electrically connected to the low-level signal line VGL, a source electrically connected to the first node N1, and a drain electrically connected to the third node N3.

The first storage capacitor C1 has one end electrically connected to the first node N1, and the other end electrically connected to the high-level signal line VGH and the source of the fourth transistor T4.

The second storage capacitor C2 has one end electrically connected to the third node N3, and the other end electrically connected to the drain of the fifth transistor T5 and the signal output Output.

The shift register shown in FIG. 1 may be a first-stage shift register in a gate driver circuit, with a signal input Input that can be connected to a frame start signal line GSTV. When the shift register is not a first-stage shift register, the input Input of the shift register is cascaded with other stages of shift registers, and a high-level signal or a second clock signal may be output from the signal output Output according to a preset timing sequence, which may be specifically implemented as described in the existing art, and details are not repeated here.

In the shift register shown in FIG. 1, to achieve a higher mobility of each transistor, the transistors may be provided as low temperature polysilicon (LTPS) thin film transistors. Due to the large number of transistors, the whole shift register occupies a relatively large area. FIG. 2 is a schematic plan view of the shift register in FIG. 1. As shown in FIG. 2, the shift register has a complicated structure, with a width of 266 μm in a row direction, and occupies a large area under a given width in a column direction, which may affect the narrow bezel design of the display substrate.

To solve at least one of the above technical problems, embodiments of the present disclosure provide a shift register, a display substrate, and a display device, which will be described in further detail below with reference to the accompanying drawings and specific implementations.

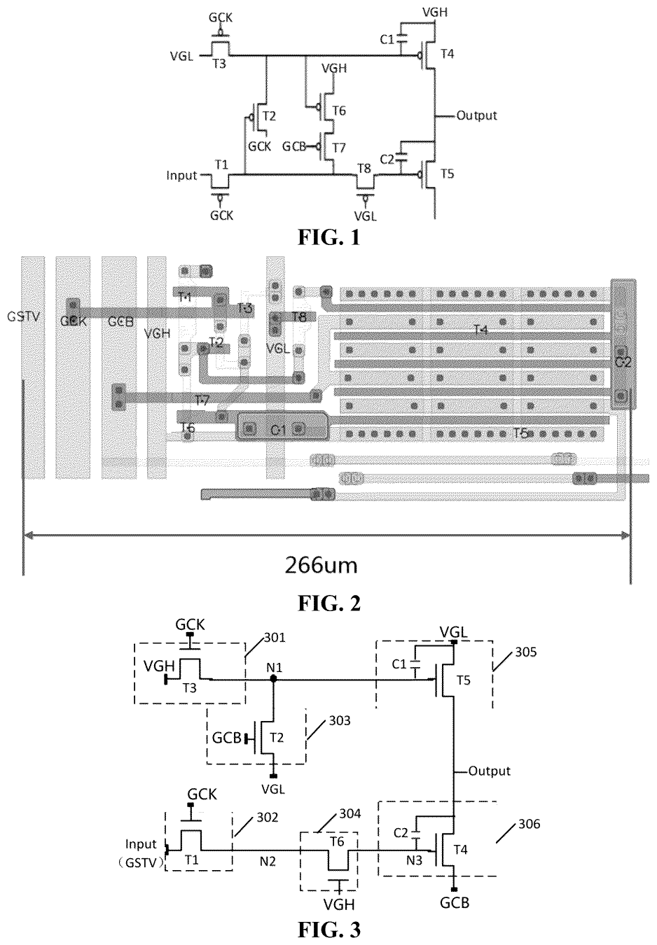

In a first aspect, an embodiment of the present disclosure provides a shift register. FIG. 3 is a schematic circuitry diagram of a shift register according to an embodiment of the present disclosure. As shown in FIG. 3, the shift register includes: a first input subcircuit 301, a second input subcircuit 302, a control subcircuit 303, a protection subcircuit 304, a first output subcircuit 305, and a second output subcircuit 306.

The first input subcircuit 301 is configured to transmit a first level signal to a first node N1 in response to a first clock signal. The first node N1 is a connection point between the first input subcircuit 301, the first output subcircuit 305, and the control subcircuit 302. The second input subcircuit 302 is configured to transmit an input signal to a second node N2 in response to the first clock signal. The second node N2 is a connection point between the second input subcircuit 302 and the protection subcircuit 304. The control subcircuit 303 is configured to input a second level signal to the first node N1 in response to a second clock signal. The protection subcircuit 304 is configured to, when the second input subcircuit 302 is working, transmit a voltage of the second node N2 to a third node N3; and when the second input subcircuit 302 is not working, input a voltage of a third node N3 to the second node N2, and enable a voltage of the second node N2 to be lower than the voltage of the third node N3. The third node N3 is a connection point between the protection subcircuit 304 and the second output subcircuit 306. The first output subcircuit 305 is configured to output the second level signal in response to a voltage of the first node N1. The second output subcircuit 306 is configured to output the second clock signal in response to the voltage of the third node N3.

In the shift register provided in the embodiments of the present disclosure, by means of the control subcircuit 303, a signal in the first input subcircuit 301 is output through the first output subcircuit 305, and a signal in the second input subcircuit 302 is output through the second output subcircuit 306, so that when the display substrate is driven to display, depending on the picture to be displayed, a scanning signal may be written to the gate lines progressively, so that pixel units in the display substrate are lightened progressively. As can be seen, the shift register provided in the embodiments of the present disclosure has a simple structure, and can reduce the number of transistors therein, which can reduce the area occupied by the shift register, facilitate a narrow bezel design of the display substrate, and thus improve the use effect of a user. Meanwhile, when the second input subcircuit 302 is not working, the protection subcircuit 304 may transmit a voltage of the third node N3 to the second node N2 to enable a voltage of the second node N2 to be lower than the voltage of the third node N3, so that the voltage of the third node N3 is prevented from being directly transmitted to the second input subcircuit 302 and breaking down a device in an inactive state in the second input subcircuit 302 due to the higher voltage. Therefore, the stability and the service life of the devices in the shift register can be improved, and the display effect can be further improved.

Specifically, as shown in FIG. 3, the first input subcircuit 301 includes: a third transistor T3. The third transistor T3 has a gate electrically connected to a first clock signal line GCK, a source electrically connected to a high-level signal line VGH, and a drain electrically connected to the first node N1. The control subcircuit 304 includes: a second transistor T2. The second transistor T2 has a gate electrically connected to a second clock signal line GCB, a source electrically connected to a low-level signal line VGL, and a drain electrically connected to the first node N1.

When the first clock signal input from the first clock signal line GCK is a high-level signal, and the second clock signal input from the second clock signal line GCB is a low-level signal, the third transistor T3 is turned on, and the second transistor T2 is turned off, so that a high-level signal input from the high-level signal line VGH can be input to the first node N1 through the third transistor T3 to charge the first node N1 and pull up a voltage of the first node N1. When the first clock signal input from the first clock signal line GCK is a low-level signal, and the second clock signal input from the second clock signal line GCB is a high-level signal, the second transistor T2 is turned on, and the third transistor T3 is turned off, so that a low-level signal input from the low-level signal line VGL can be input to the first node N1 through the second transistor T2 to pull down the voltage of the first node N1.

With continued reference to FIG. 3, the second input subcircuit 302 includes: a first transistor T1. The first transistor T1 has a gate electrically connected to a first clock signal line GCK, a source electrically connected to a signal input Input, and a drain electrically connected to the second node N2. The protection subcircuit 303 includes: a sixth transistor T6. The sixth transistor T6 has a gate electrically connected to the high-level signal line VGH, a source electrically connected to the second node N2, and a drain electrically connected to the third node N3.

When the first clock signal line GCK is a high-level signal line, the first transistor T1 is turned on, so that a high-level signal (which may be a frame start signal) input from the signal input can be input to the second node N2 through the first transistor T1 to charge the second node N2 and pull up a voltage of the second node N2. Meanwhile, the sixth transistor T6 is in a normally-on state under the control of the high-level signal, and a voltage of the second node N2 is transmitted to the third node N3 through the sixth transistor T6. When the first clock signal line GCK is a low-level signal line, the first transistor T1 is turned off. At this time, since the third node N3 is in a high-voltage state after being charged for a long time, if the voltage is directly transmitted to the drain of the first transistor T1 which is turned off, the first transistor T1 can be easily broken down and damaged. Since the sixth transistor T6 is in a normally-on state and has a certain impedance, the voltage of the third node N3 can be well reduced in the process of being transmitted to the second node N2 while the first transistor T2 is prevented from being broken down, thereby ensuring stable performance of the first transistor T1.

With continued reference to FIG. 3, the first output subcircuit 305 includes: a fifth transistor T5 and a first storage capacitor C1. The fifth transistor T5 has a gate electrically connected to the first node N1, a source electrically connected to a low-level signal line VGL, and a drain electrically connected to a signal output Output. The first storage capacitor C1 has one end electrically connected to the first node N1, and the other end electrically connected to the low-level signal line VGL. The second output subcircuit 306 includes: a fourth transistor T4 and a second storage capacitor C2. The fourth transistor T4 has a gate electrically connected to the third node N3, a source electrically connected to the second clock signal line GCB, and a drain electrically connected to the signal output Output. The second storage capacitor C2 has one end electrically connected to the third node N3, and the other end electrically connected to the signal output Output.

When the voltage of the first node N1 is a high-level signal voltage, the fifth transistor T5 is turned on, so that a low-level signal input from the low-level signal line VGL can be output from the signal output Output. Meanwhile, when the voltage of the third node N3 is a high-level signal voltage, the fourth transistor T4 is turned on, so that a low-level signal in the second clock signal input from the second clock signal line GCB can be output from the signal output Output. At this time, the low-level signal in the second clock signal is the same as the level signal input from the low-level signal line VGL. When the voltage of the first node N1 is a level signal, the fifth transistor T5 is turned off, and when the voltage of the third node N3 is a high-level signal voltage, the fourth transistor T4 is turned on, so that a high-level signal in the second clock signal input from the second clock signal line GCB can be output from the signal output Output.

In some embodiments, a width-to-length ratio of the second transistor T2 is greater than a width-to-length ratio of the third transistor T3.

In practical applications, the width-to-length ratio of the second transistor T2 can be appropriately increased to allow higher stability of the second transistor T2, so that the second transistor T2 can transmit a larger current. When the second transistor T2 is turned on, a low-level signal input from the low-level signal line VGL can be stably input to the first node N1, so that the fifth transistor T5 can be controlled to be completely turned off to prevent leakage current, thereby further improving the stability of signal output from the signal output Output.

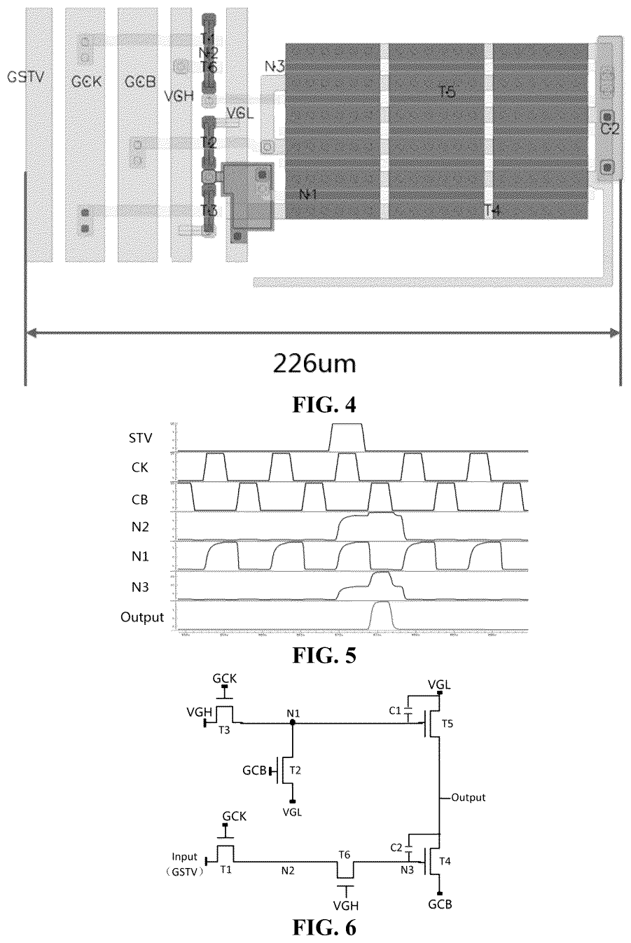

FIG. 4 is a schematic plan view of the shift register in FIG. 3. As shown in FIG. 4, the shift register is provided with only 6 transistors, which, compared with the structure of the shift register shown in FIGS. 1 and 2, can significantly reduce the number of transistors and simplify the circuit structure. Meanwhile, a width of the shift register in a row direction is 226 μm, which is reduced by 40 μm, i.e., 15%, compared with the width of the shift register shown in FIGS. 1 and 2, which can facilitate a narrow bezel design of the display substrate, and thus improve the use effect of a user.

FIG. 5 is a timing diagram of the shift register in FIG. 3. The working principle of the shift register provided in the embodiments of the present disclosure will be described in further detail below in conjunction with the timing diagram.

In a first stage, a signal on the first clock signal line GCK is a high-level signal, and a signal on the second clock signal line GCB is a low-level signal. The first transistor T1 and the third transistor T3 are both turned on, while the second transistor T2 is turned off, so that a high-level signal input from the high-level signal line VGH can charge the first node N1, and a frame start signal input from the signal input can charge the second node N2 and the third node N3, so that the voltages of the first node N1, the second node N2, and the third node N3 are all high level voltages. At this time, both the fourth transistor T4 and the fifth transistor T5 are turned on, and a low-level signal input from the low-level signal line VGL and the low-level signal input from the second clock signal line GCB reset the voltage at the signal output Output.

In a second stage, the signal on the first clock signal line GCK is a low-level signal, and the signal on the second clock signal line GCB is a high-level signal. The first transistor T1 and the third transistor T3 are both turned off, while the second transistor T2 is turned on, so that the voltage of the first node N1 is pulled down by the low-level signal input from the low-level signal line VGL, and the fourth transistor T4 is turned off. The voltage of the third node N3 maintains a high-level signal state under the action of the second storage capacitor C2, the fifth transistor T5 is turned on, and the high-level signal of the second clock signal GCB is output from the signal output Output.

In a third stage, the signal on the first clock signal line GCK is a high-level signal, and the signal on the second clock signal line GCB is a low-level signal. The first transistor T1 and the third transistor T3 are both turned on, while the second transistor T2 is turned off, so that the voltage of the first node N1 is pulled up again, the fourth transistor T4 is turned on, and the low-level signal input from the low-level signal line VGL is output from the signal output Output. At this time, a low-level signal is input from the signal input Input, and the fifth transistor T5 is turned off.

In a fourth stage, the signal on the first clock signal line GCK is a low-level signal and the signal on the second clock signal line GCB is a high-level signal. The first transistor T1 and the third transistor T3 are both turned off, while the second transistor T2 is turned on, so that the voltage of the first node N1 is pulled down by the low-level signal input from the low-level signal line VGL, and the fourth transistor T4 is turned off. Meanwhile, a low-level signal is input from the signal input Input, the fifth transistor T5 is turned off, and no signal is output from the signal output Output so that the signal output Output is in a noise reduction state.

In a second aspect, an embodiment of the present disclosure further provides a shift register. FIG. 6 is a schematic circuitry diagram of another shift register according to an embodiment of the present disclosure. As shown in FIG. 6, the shift register includes: a first transistor T1, a second transistor T2, a third transistor T3, a fourth transistor T4, a fifth transistor T5, a sixth transistor T6, a first storage capacitor C1, and a second storage capacitor C2. The third transistor T3 has a gate electrically connected to a first clock signal line GCK, a source electrically connected to a high-level signal line VGH, and a drain electrically connected to a first node N1. The second transistor T2 has a gate electrically connected to a second clock signal line GCB, a source electrically connected to a low-level signal line VGL, and a drain electrically connected to the first node N1. The first transistor T1 has a gate electrically connected to the first clock signal line GCK, a source electrically connected to a signal input Input, and a drain electrically connected to a second node N2. The sixth transistor T6 has a gate electrically connected to the high-level signal line VGH, a source electrically connected to the second node N2, and a drain electrically connected to a third node N3. The fifth transistor T5 has a gate electrically connected to the first node N1, a source electrically connected to the low-level signal line VGL, and a drain electrically connected to a signal output Output. The first storage capacitor C1 has one end electrically connected to the first node N1, and the other end electrically connected to the low-level signal line VGL. The fourth transistor T4 has a gate electrically connected to the third node N3, a source electrically connected to the second clock signal line GCB, and a drain electrically connected to the signal output Output. The second storage capacitor C2 has one end electrically connected to the third node N3, and the other end electrically connected to the signal output Output.

The shift register provided in the embodiment of the present disclosure is a specific circuit structure of the shift register according to any one of the above embodiments, and based on the same implementation principle as the shift register according to any one of the above embodiments, which is not repeated here.

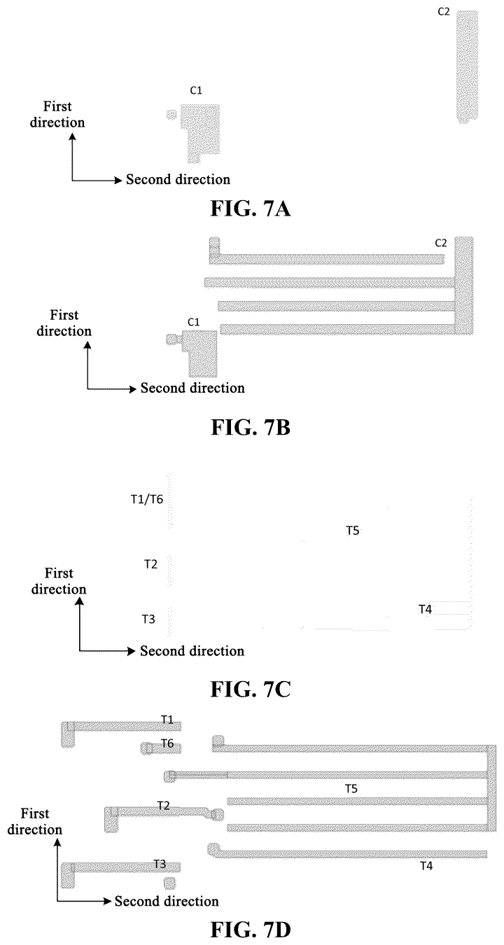

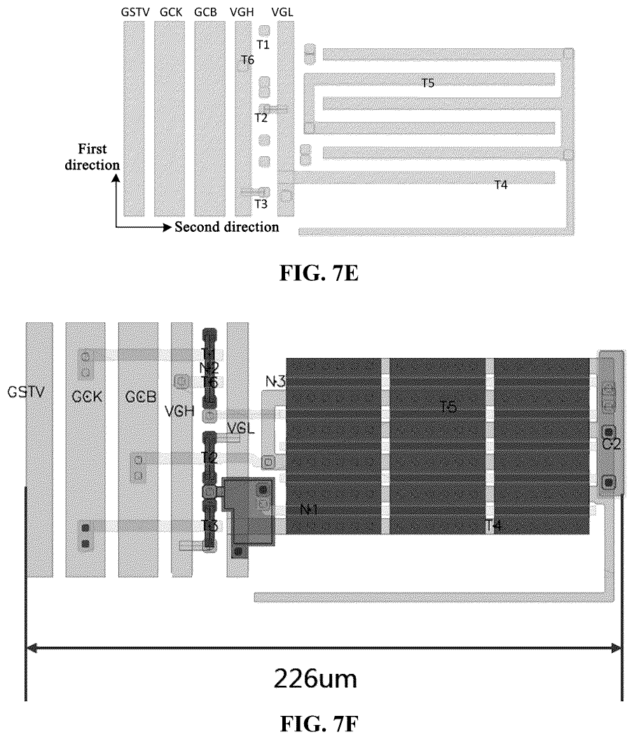

In a third aspect, an embodiment of the present disclosure provides a display substrate, including: a base substrate (not shown), and a plurality of shift registers, each being the shift register according to any one of the above embodiments, cascaded together on the base substrate. FIGS. 7A to 7F are schematic structural diagrams of various layers in a display substrate according to an embodiment of the present disclosure, and the display substrate provided in the embodiments of the present disclosure will be described in further detail below with reference to the structures of the various layers.

FIG. 7A is a schematic structural diagram of a first gate conductive layer in a display substrate according to an embodiment of the present disclosure. As shown in FIG. 7a, a first gate conductive layer includes: first plates of a first storage capacitor C1 and a second storage capacitor C2, and a connection line electrically connecting the first plates.

FIG. 7B is a schematic structural diagram of a second gate conductive layer in a display substrate according to an embodiment of the present disclosure. As shown in FIG. 7b, a second gate conductive layer includes: second plates of a first storage capacitor C1 and a second storage capacitor C2, and a connection line electrically connecting the second plates. The first gate conductive layer and the second gate conductive layer are both formed on the base substrate, and accordingly, orthographic projections of the first plates and the second plates on the base substrate are overlapped to form a first storage capacitor C1 and a second storage capacitor C2, respectively.

FIG. 7C is a schematic structural diagram of a semiconductor layer in a display substrate according to an embodiment of the present disclosure. As shown in FIG. 7c, the semiconductor layer includes: active layers of a first transistor T1, a second transistor T2, a third transistor T3, a fourth transistor T4, a fifth transistor T5, and a sixth transistor T6. The active layer of each transistor is made of an oxide material, such as a metal oxide, for example, indium gallium zinc oxide (IGZO).

FIG. 7D is a schematic structural diagram of a third gate conductive layer in a display substrate according to an embodiment of the present disclosure. As shown in FIG. 7d, a third gate conductive layer includes: gates of the first transistor T1, the second transistor T2, the third transistor T3, the fourth transistor T4, the fifth transistor T5 and the sixth transistor T6, and connection lines electrically connecting the gates.

FIG. 7E is a schematic structural diagram of a source/drain conductive layer in a display substrate according to an embodiment of the present disclosure. As shown in FIG. 4e, a source/drain conductive layer includes: sources and drains of the first transistor T1, the second transistor T2, the third transistor T3, the fourth transistor T4, the fifth transistor T5, and the sixth transistor T6; a frame start signal line GSTV, a first clock signal line GCK, a second clock signal line GCB, a high-level signal line VGH, and a low-level signal line VGL; and connection lines electrically connecting the sources, the drains, and the signal lines.

FIG. 7F is a laminated structure of the layers in FIGS. 7A to 7E. The structures of the layers described above may be stacked together to form a shift register in the display substrate, which has the same structure as that shown in FIG. 4.

With continued reference to FIGS. 7E and 7F, the display substrate further includes: a plurality of clock signal lines and a plurality of power signal lines. The clock signal lines include at least: a first clock signal line GCK and a second clock signal line GCB; and the power signal lines include at least: a high-level signal line VGH and a low-level signal line VGL. The plurality of clock signal lines and the plurality of power signal lines extend in a first direction, and are arranged side by side in a second direction. The second direction is intersected with the first direction. A width of each clock signal line in the second direction is greater than a width of each power signal line in the second direction.

In the embodiments of the present disclosure, the first direction may be a row direction of the display substrate, and the second direction may be a column direction of the display substrate. The first clock signal line GCK, the second clock signal line GCB, the high-level signal line VGH, and the low-level signal line VGL may extend in the same direction (first direction), i.e., the column direction. The first clock signal line GCK and the second clock signal line GCB of the clock signal lines transmit voltage signals which are changed constantly, while the high-level signal line VGH and the low-level signal line VGL of the power signal lines transmit stable voltage signals. To avoid the generation of a large parasitic capacitance by the clock signal lines, a width of each clock signal line in the second direction is greater than a width of each power signal line in the second direction. For example, a width of the first clock signal line GCK in the second direction is greater than a width of the high-level signal line VGH in the second direction, thereby ensuring efficient transmission of signals. It should be noted here that, taking the first clock signal line GCK as an example, the first clock signal line GCK is not a straight line, but generally extends in the first direction with bends at some positions. For a certain segment of a bend, it may extend in the second direction, and then the width of the first clock signal line GCK in the second direction may be a length of the segment in the second direction.

With continued reference to FIG. 7c, a first transistor T1, a second transistor T2, a third transistor T3, and a sixth transistor T6 are in a first transistor group. Active layers in the first transistor group are arranged in a first direction, and arranged side by side in the first direction.

Drains of the first transistor T1 and the sixth transistor T6 are connected with each other. In practical applications, the active layers of the first transistor T1 and the sixth transistor T6 may be directly connected with each other, which means that the active layers of the two form an integral part, thereby reducing the processes of punching and the like when forming the drains, and saving the manufacturing cost.

The transistors may be divided into multiple groups depending on their positions in the display substrate relative to the power supply signal lines. For example, the first transistor T1, the second transistor T2, the third transistor T3, and the sixth transistor T6 may be in a first transistor group, and the fourth transistor T4 and the fifth transistor T5 may be in a second transistor group.

The active layers of the first transistor group may each have a rectangular shape, with longer sides arranged in the first direction, i.e., the column direction, and shorter sides arranged in the second direction, i.e., the row direction. The active layers in the first transistor group may be divided into three parts, i.e., a first part including the active layers of the first transistor T1 and the sixth transistor T6, a second part including the active layer of the second transistor T2, and a third part including the active layer of the third transistor. Active layers in the first transistor group may be arranged in a first direction, and arranged side by side in the first direction, which can reduce a width in the row direction occupied by each active layer in the first transistor group, and thus reduce the width of whole shift register in the display substrate, thereby facilitating a narrow bezel design of the display substrate, and further improving the use effect of a user.

With continued reference to FIGS. 7C, 7E and 7F, each active layer in the first transistor group is between adjacent power signal lines, and a width of each active layer in the second direction is less than a distance between the adjacent power signal lines.

Since the high-level signal line VGH and the low-level signal line VGL transmit stable voltage signals without interfering with other conductive layers, each active layer in the first transistor group may be disposed between the high-level signal line VGH and the low-level signal line VGL, with a width in the second directionless than a distance between the adjacent high-level signal line VGH and low-level signal line VGL, so that the widths occupied by the first transistor T1, the second transistor T2, the third transistor T3 and the sixth transistor T6 in the first transistor group in the first direction can be further reduced, thereby reducing the width of the whole shift register, facilitating a narrow bezel design of the display substrate, and further improving the use effect of a user.

With continued reference to FIGS. 7C, 7E and 7F, a width of each active layer in the first transistor group in the second direction is less than the width of each clock signal line in the second direction, and greater than or equal to the width of each power signal line in the second direction.

Since the first transistor T1, the second transistor T2, the third transistor T3, and the sixth transistor T6 in the first transistor group do not directly output to the pixel circuit in the display region, their active layers may occupy a smaller width in the second direction. For example, the width of each active layer in the second direction may be less than the width of the clock signal line (the first clock signal line GCK or the second clock signal line GCB) in the second direction, and greater than or equal to the width of the power signal line (the high-level signal line VGH or the low-level signal line VGL) in the second direction, so that the width occupied by each transistor in the row direction can be reduced while ensuring stable performance of the transistor, thereby reducing the width of the whole shift register, facilitating a narrow bezel design of the display substrate, and further improving the use effect of a user.

In some embodiments, as shown in FIG. 7f, a width of the first transistor group in the second direction is less than the width of each clock signal line in the second direction, and greater than or equal to the width of each power signal line in the second direction.

The first transistor T1, the second transistor T2, the third transistor T3, and the sixth transistor T6 in the first transistor group are arranged side by side in the first direction, which means that the first transistor group as a whole is arranged in the first direction, and a width of the first transistor group in the second direction is the width of each transistor in the second direction. The width of each transistor in the second direction includes not only the width of the active layer in the second direction, but also a width of the whole thin film transistor, including the source, the drain, the gate, and other structures, in the second direction. If the transistors have different widths in the second direction, the largest width of the transistors in the second direction is the width of the first transistor group in the second direction. For example, the width of the first transistor group in the second direction may be less than the width of the clock signal line (the first clock signal line GCK or the second clock signal line GCB) in the second direction, and greater than or equal to the width of the power signal line (the high-level signal line VGH or the low-level signal line VGL) in the second direction, so that the width occupied by the first transistor group in the row direction can be reduced while ensuring stable performance of each transistor in the first transistor group, thereby reducing the width of the whole shift register, facilitating a narrow bezel design of the display substrate, and further improving the use effect of a user.

With continued reference to FIGS. 7C, 7E and 7F, the fourth transistor T4 and the fifth transistor T5 are in a second transistor group. Active layers in the second transistor group are arranged in a first direction, and arranged side by side in a second direction.

As output transistors, the fourth transistor T4 and the fifth transistor T5 in the second transistor group directly output to the pixel circuit in the display region, and may be disposed in a different region from the first transistor T1, the second transistor T2, the third transistor T3 and the sixth transistor T6 in the first transistor group, so as to ensure the performance of the fourth transistor T4 and the fifth transistor T5 in the second transistor group, and improve the stability of the output gate drive signal. Specifically, active layers in the second transistor group may be arranged in the first direction, and arranged side by side in the second direction, to increase the area of each active layers in the second transistor group. Meanwhile, instead of being disposed between adjacent signal lines, the active layers may be arranged on a side of the power signal lines away from the clock signal lines, to form an active layer with a larger area, and ensure stable performance of the output transistors.

With continued reference to FIGS. 7C, 7E and 7F, a width of each active layer in the second transistor group in the second direction is greater than a width of each clock signal line in the second direction.

Larger widths of the active layers in the second transistor group in the second direction, for example, the case where a width of each active layer in the second transistor group in the second direction is greater than the width of the clock signal line (the first clock signal line GCK or the second clock signal line GCB), can ensure that the fourth transistor T4 and the fifth transistor T5 in the second transistor group have higher stability as a whole, thereby improving the stability of the output gate drive signal.

With continued reference to FIG. 7A, and 7B to 7F, an orthographic projection of the first storage capacitor C1 on the base substrate is between an orthographic projection of the high-level signal line VGH on the base substrate and an orthographic projection of the fourth transistor T4 on the base substrate; and an orthographic projection of the second storage capacitor C2 on the base substrate is on a side of an orthographic projection of the fifth transistor T5 on the base substrate away from the low-level signal line VGL.

The first storage capacitor C1 and the layers of the transistors are disposed in different layers. The first storage capacitor C1 may be disposed between the high-level signal line VGH and the fourth transistor T4, to facilitate stable electrical connection between the first storage capacitor C1 and the respective transistors. Likewise, the second storage capacitor C2 may be disposed on a side of the fifth transistor T5 away from the low-level signal line VGL, to facilitate stable electrical connection between the second storage capacitor C2 and the respective transistors.

With continued reference to FIG. 7A, and 7B to 7F, the orthographic projection of the first storage capacitor C1 on the base substrate is at least partially overlapped with the orthographic projection of the low-level signal line VGL on the base substrate.

The first storage capacitor C1 and the layers of the transistors may be disposed in different layers, and an orthographic projection of the first storage capacitor C1 on the base substrate may be at least partially overlapped with the orthographic projection of the low-level signal line VGL on the base substrate, so that the width occupied by the first storage capacitor C1 in the row direction can be further reduced, thereby reducing the width of the whole shift register, facilitating a narrow bezel design of the display substrate, and further improving the use effect of a user. Meanwhile, the first storage capacitor C1 and the second storage capacitor C2 may each have a rectangular or quasi-rectangular shape, with longer sides arranged in the first direction and shorter sides arranged in the second direction, so that the widths occupied by the first storage capacitor C1 and the second storage capacitor C2 in the row direction can be further reduced, thereby reducing the width of the whole shift register, facilitating a narrow bezel design of the display substrate, and further improving the use effect of a user.

In a fourth aspect, an embodiment of the present disclosure provides a display device, including the shift register and the display substrate according to any of the above embodiments. The display device may be a television, a mobile phone, a monitor, a laptop, a digital album, a navigator or any other product or component having a display function. The implementation principle of the display device is similar to that of the shift register and the display substrate described above, and thus is not repeated here.

It will be appreciated that the above implementations are merely exemplary implementations for the purpose of illustrating the principle of the present disclosure, and the present disclosure is not limited thereto. Various modifications and improvements can be made by a person having ordinary skill in the art without departing from the spirit and essence of the disclosure. Accordingly, all of the modifications and improvements also fall within the protection scope of the present disclosure.

1. A shift register, wherein the shift register comprises: a first input subcircuit, a second input subcircuit, a control subcircuit, a protection subcircuit, a first output subcircuit, and a second output subcircuit;
the first input subcircuit is configured to transmit a first level signal to a first node in response to a first clock signal; and the first node is a connection point between the first input subcircuit, the first output subcircuit, and the control subcircuit;
the second input subcircuit is configured to transmit an input signal to a second node in response to the first clock signal; and the second node is a connection point between the second input subcircuit and the protection subcircuit;
the control subcircuit is configured to input a second level signal to the first node in response to a second clock signal;
the protection subcircuit is configured to, when the second input subcircuit is working, transmit a voltage of the second node to a third node; and when the second input subcircuit is not working, input a voltage of the third node to the second node, and enable the voltage of the second node to be lower than the voltage of the third node; and the third node is a connection point between the protection subcircuit and the second output subcircuit;
the first output subcircuit is configured to output the second level signal in response to a voltage of the first node; and
the second output subcircuit is configured to output the second clock signal in response to the voltage of the third node.

2. The shift register according to claim 1, wherein the first input subcircuit comprises: a third transistor; wherein
the third transistor has a control electrode electrically connected to a first clock signal line, a first electrode electrically connected to a first level signal line, and a second electrode electrically connected to the first node.

3. The shift register according to claim 2, wherein the second input subcircuit comprises: a first transistor; wherein
the first transistor has a control electrode electrically connected to the first clock signal line, a first electrode electrically connected to a signal input, and a second electrode electrically connected to the second node.

4. The shift register according to claim 3, wherein the protection subcircuit comprises: a sixth transistor; wherein
the sixth transistor has a control electrode electrically connected to the first level signal line, a first electrode electrically connected to the second node, and a second electrode electrically connected to the third node.

5. The shift register according to claim 4, wherein the control subcircuit comprises: a second transistor; wherein
the second transistor has a control electrode electrically connected to a second clock signal line, a first electrode electrically connected to a second level signal line, and a second electrode electrically connected to the first node.

6. The shift register according to claim 5, wherein the first output subcircuit comprises: a fifth transistor and a first storage capacitor;
the fifth transistor has a control electrode electrically connected to the first node, a first electrode electrically connected to the second level signal line, and a second electrode electrically connected to a signal output; and
the first storage capacitor has one end electrically connected to the first node, and the other end electrically connected to the second level signal line.

7. The shift register according to claim 6, wherein the second output subcircuit comprises: a fourth transistor and a second storage capacitor;
the fourth transistor has a control electrode electrically connected to the third node, a first electrode electrically connected to the second clock signal line, and a second electrode electrically connected to the signal output; and
the second storage capacitor has one end electrically connected to the third node, and the other end electrically connected to the signal output.

8. The shift register according to claim 1,
wherein the transistors in the subcircuits are all oxide thin film transistors,
wherein a width-to-length ratio of the second transistor is greater than a width-to-length ratio of the third transistor.

9. (canceled)

10. A shift register, wherein the shift register comprises: a first transistor, a second transistor, a third transistor, a fourth transistor, a fifth transistor, a sixth transistor, a first storage capacitor, and a second storage capacitor;
the third transistor has a control electrode electrically connected to a first clock signal line, a first electrode electrically connected to a first level signal line, and a second electrode electrically connected to a first node;
the first transistor has a control electrode electrically connected to the first clock signal line, a first electrode electrically connected to a signal input, and a second electrode electrically connected to a second node;
the sixth transistor has a control electrode electrically connected to the first level signal line, a first electrode electrically connected to the second node, and a second electrode electrically connected to a third node;
the second transistor has a control electrode electrically connected to a second clock signal line, a first electrode electrically connected to a second level signal line, and a second electrode electrically connected to the first node;
the fifth transistor has a control electrode electrically connected to the first node, a first electrode electrically connected to the second level signal line, and a second electrode electrically connected to a signal output;
the first storage capacitor has one end electrically connected to the first node, and the other end electrically connected to the second level signal line;
the fourth transistor has a control electrode electrically connected to the third node, a first electrode electrically connected to the second clock signal line, and a second electrode electrically connected to the signal output; and
the second storage capacitor has one end electrically connected to the third node, and the other end electrically connected to the signal output.

11. A display substrate, wherein the display substrate comprises: a base substrate, and a plurality of shift registers, each being the shift register according to claim 1, cascaded together on the base substrate.

12. The display substrate according to claim 11, wherein the display substrate further comprises: a plurality of clock signal lines and a plurality of power signal lines; the clock signal lines comprise at least: a first clock signal line and a second clock signal line; and the power signal lines comprise at least: a first level signal line and a second level signal line;
the plurality of clock signal lines and the plurality of power signal lines extend in a first direction, and are arranged side by side in a second direction, wherein the first direction is intersected with the second direction; and
a width of each clock signal line in the second direction is greater than a width of each power signal line in the second direction.

13. The display substrate according to claim 12, wherein a first transistor, a second transistor, a third transistor, and a sixth transistor in each shift register are in a first transistor group; and
active layers in the first transistor group are arranged in the first direction, and arranged side by side in the first direction.

14. The display substrate according to claim 13, wherein each active layer in the first transistor group is between adjacent power signal lines, and a width of each active layer in the second direction is less than a distance between the adjacent power signal lines.

15. The display substrate according to claim 14, wherein a width of each active layer in the first transistor group in the second direction is less than the width of each clock signal line in the second direction, and greater than or equal to the width of each power signal line in the second direction.

16. The display substrate according to claim 15, wherein a width of the first transistor group in the second direction is less than the width of each clock signal line in the second direction, and greater than or equal to the width of each power signal line in the second direction.

17. The display substrate according to claim 12, wherein a fourth transistor and a fifth transistor in each of the shift registers are in a second transistor group; and
active layers in the second transistor group are arranged in the first direction, and are arranged side by side in the second direction.

18. The display substrate according to claim 17, wherein each active layer in the second transistor group is on a side of the power signal lines away from the clock signal lines.

19. The display substrate according to claim 17, wherein a width of each active layer in the second transistor group in the second direction is greater than a width of each clock signal line in the second direction.

20. The display substrate according to claim 12, wherein an orthographic projection of the first storage capacitor on the base substrate is between an orthographic projection of the first level signal line on the base substrate and an orthographic projection of the fourth transistor on the base substrate; and
an orthographic projection of the second storage capacitor on the base substrate is on a side of an orthographic projection of the fifth transistor on the base substrate away from the second level signal line.

21. The display substrate according to claim 20, wherein the orthographic projection of the first storage capacitor on the base substrate is at least partially overlapped with the orthographic projection of the second level signal line on the base substrate.

22. (canceled)
